(19) United States
(12) Patent Application Publication
(10) Pub. No.: US 2017/0057827 A1
(43) Pub. Date: Mar. 2, 2017

(54) GRAPHENE TRANSPARENT CONDUCTIVE ELECTRODE

(71) Applicant: U.S.A. as represented by the Administrator of the National Aeronautics and Space Administration, Washington, DC (US)

(72) Inventors: Mahmooda Sultana, Laurel, MD (US); Mary J. Li, Bethesda, MD (US); Larry A. Hess, Poolesville, MD (US)

(21) Appl. No.: 14/843,125

(22) Filed: Sep. 2, 2015

(51) Int. Cl. C01B 31/04; C23C 16/50; H01L 31/18; G02B 26/04; H01L 21/3215; H01L 21/02; H01L 29/49; H01L 31/0224; C23C 16/455; H01L 21/285

(52) U.S. Cl. CPC C01B 31/0484; C23C 16/455; C23C 16/50; H01L 31/1884; H01L 21/28556; H01L 21/28525; H01L 21/3215; H01L 21/02068; H01L 29/4966; H01L 31/022466; G02B 26/04; C01B 2204/30

(57) ABSTRACT

Methods of fabricating graphene for device application are described herein. The method comprises growing a graphene film on a copper substrate using chemical vapor deposition (CVD), transferring the graphene film from the copper substrate to a device substrate, doping the graphene film with gold(III) chloride (AuCl3); and patterning the graphene film. The graphene film has a transmittance of at least 97% in visible to infrared range and a sheet resistance of less than 200 Ohms per square. The graphene film can be used as a transparent conductive electrode in, among others, a microshutter array on a space telescope.

### WORKS BY GOVERNMENT EMPLOYEES ONLY

The embodiments described herein were made by employees of the United States Government, and may be manufactured and used by or for the Government for governmental purposes without the payment of any royalties thereon or therefor.

### BACKGROUND

The following description is provided to assist the understanding of the reader. None of the information provided or references cited is admitted to be prior art.

Graphene is a single layer of carbon atoms packed in a hexagon crystal lattice. Graphene has attractive physical properties, such as low electrical resistance, high optical transmittance, and excellent mechanical flexibility, which makes it a candidate for transparent conductive electrodes. Transparent conductive electrodes are used in various optoelectronic devices, such as microshutter arrays on space telescopes, liquid crystal displays (LCDs), photovoltaic devices, organic light-emitting diodes (OLEDs), etc. An ideal transparent electrode has a low electrical resistance and high optical transmittance.

Chemical vapor deposition (CVD) provides a method for synthesizing large-scale graphene films. For example, CVD growth of graphene films on copper substrates allows for mass production of large area monolayer graphene films. The sheet resistance of these films, however, is several hundred Ohms per square, significantly larger than theoretically expected resistance of monolayer graphene film. Therefore, a method for making large-scale graphene with low resistance and high transmittance suitable for transparent conductive electrode in device applications is needed.

### SUMMARY

A method of fabricating graphene for device applications is described herein. The method comprises growing a graphene film on a copper substrate using chemical vapor deposition (CVD), transferring the graphene film from the copper substrate to a device substrate, doping the graphene film with gold(III) chloride (AuCl₃), and patterning the graphene film for device applications.

In some embodiments, the CVD growth of the graphene film on the copper substrate further comprises heating the copper substrate in a CVD reactor to a temperature of about 850° C. to about 1000° C. under an ambient pressure of hydrogen (H₂), or argon (Ar), or a mixture thereof, introducing reactions gas mixtures to the CVD reactor, and growing graphene on the copper substrate. In some embodiments, the reaction gas mixtures include flowing methane (CH₄) of about 1 to about 20 standard cubic centimeters per minute (sccm), flowing H₂ of about 5 to about 50 sccm, and flowing Ar of about 200 to about 1000 sccm. In some embodiments, the transfer of the graphene film from the copper substrate to the device substrate further comprises attaching a polymer support to the graphene film on the copper substrate to form a stack, placing the stack in a copper etchant to remove the copper substrate, attaching a device substrate to the graphene film; and removing the polymer support. In some embodiments, the doping the graphene film with AuCl₃ comprises spinning a AuCl₃ in nitromethane (CH3NO2) solution having a concentration of 0.001 mole per liter to 0.05 mole per liter on the graphene film at 2000 revolutions per minute for about 60 seconds. In some embodiments, the patterning the graphene film comprises etching the graphene film with oxygen plasma.

In another aspect, a monolayer graphene film doped with AuCl₃ is provided. In some embodiments, the doped graphene film has a transmittance of at least 97% in the visible to infrared range and a sheet resistance of less than 200 Ohms per square. In some embodiments, the sheet resistance is less than 100 Ohms per square. In some embodiments, the sheet resistance is less than 60 Ohms per square.

In another aspect, A device comprising a graphene transparent conductive electrode is provided. The graphene transparent conductive electrode comprises a graphene film doped with AuCl₃, and has a transmittance of at least 97% in visible to infrared range and a sheet resistance of less than 200 Ohms per square. In some embodiments, the device comprises a transparent substrate in a microshutter array on a space telescope. In some embodiments, the device comprises a photovoltaic device. In some embodiments, the device comprises a field effect transistor.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

FIG. 1 is a flow diagram illustrating fabrication process of graphene as transparent conductive electrode for device applications in accordance with an illustrative embodiment.

FIG. 2 depicts a schematic view of a monolayer graphene film in accordance with an illustrative embodiment.

FIG. 3 is a scanning electron microscopy (SEM) image of a monolayer graphene film on a copper substrate in accordance with an illustrative embodiment.

FIG. 4 depicts a Raman spectrum of a monolayer graphene film on a copper substrate in accordance with an illustrative embodiment.

FIG. 5 depicts a schematic view of a process of transferring a graphene film from a copper substrate to a device substrate in accordance with an illustrative embodiment.

FIG. 6 is a graph illustrating transmittances of an undoped graphene film and a doped graphene film in accordance with an illustrative embodiment.

FIG. 7 depicts a schematic cross-sectional view of a device with graphene transparent conductive electrodes in accordance with an illustrative embodiment.

FIG. 8 depicts a schematic perspective view of a microshutter array with graphene transparent conductive electrodes in accordance with an illustrative embodiment.

FIG. 9 depicts a schematic cross-sectional view of a photovoltaic device with graphene transparent conductive electrode in accordance with an illustrative embodiment.

FIG. 10 depicts a schematic cross-sectional view of a field effect transistor (FET) device with graphene transparent conductive electrode in accordance with an illustrative embodiment.

### DETAILED DESCRIPTION

In the following detailed description, reference is made to the accompanying drawings, which from a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

The present disclosure relates to graphene and more particularly to graphene transparent conductive electrodes in device applications. A monolayer graphene film was grown on a copper substrate and transferred from the copper substrate to a device substrate. The graphene film was then doped with gold chloride and patterned to be electrodes for device applications. Enhanced electrical and optical properties were achieved on the same graphene films. More particularly, a 97% transmittance in the visible and infrared range and a sheet resistance lower than 200 Ohms per square were achieved. Large area graphene films enabled photolithography process and reactive ion etching (RIE) process. The method thus provides graphene films ready for use in device applications.

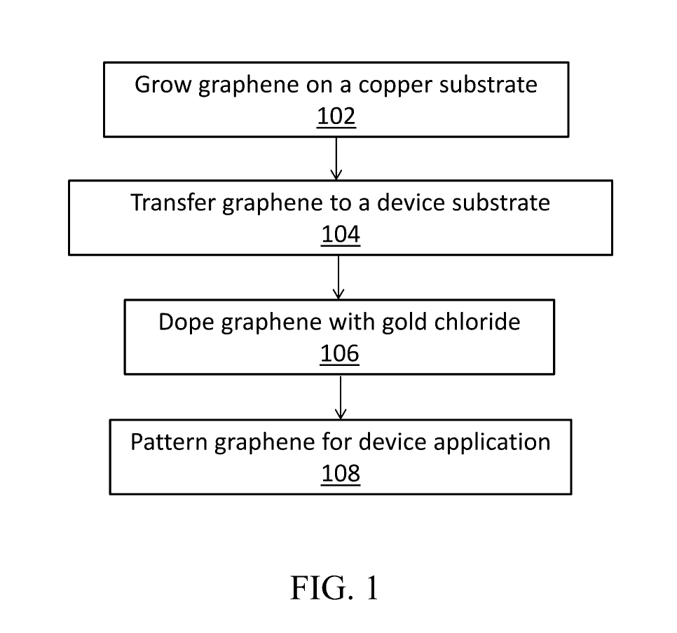

Now refer to FIG. 1. FIG. 1 is a flow diagram illustrating fabrication process of graphene as transparent conductive electrode for device applications in accordance with an illustrative embodiment. In alternative embodiments, fewer, additional, and/or different operations may be performed. Also, the use of a flow diagram is not meant to be limiting with respect to the order of operations performed.

In an operation 102, a graphene film was grown on a copper substrate using a chemical vapor deposition (CVD). Thin layers of copper, for example, copper coils, were used as the CVD substrate in some embodiments. It shall be appreciated that other types of thin copper layer, for example, a copper film on a silicon substrate, may also be used as the CVD substrate. The copper substrates were placed in a quartz tube of a CVD reactor. In some embodiments, the copper substrates in the tube were heated up to 850° C.-1000° C. under ambient pressure with flowing hydrogen (H₂) and/or argon (Ar). Flowing reaction gas mixtures were then introduced into the reaction chamber. In some embodiments, the reaction gas mixtures included methane (CH₄) with a flow rate of 1-20 standard cubic centimeters per minute (sccm), H₂ with a flow rate of 5-50 sccm, and Ar with a flow rate of 20-1000 sccm. In the graphene deposition process, CH₄ was initially decomposed to give a mixture of carbon (C) and H₂, and the C atoms were condensed on the copper substrates to form graphene films. In some embodiments, the growth process was carried out for about 30 to 60 minutes. Then the system was cooled down at a rate of approximately 25° C. per minute to 35° C. per minute to about 300° C., followed by a natural cooling to room temperature. The samples were removed from the CVD reactor.

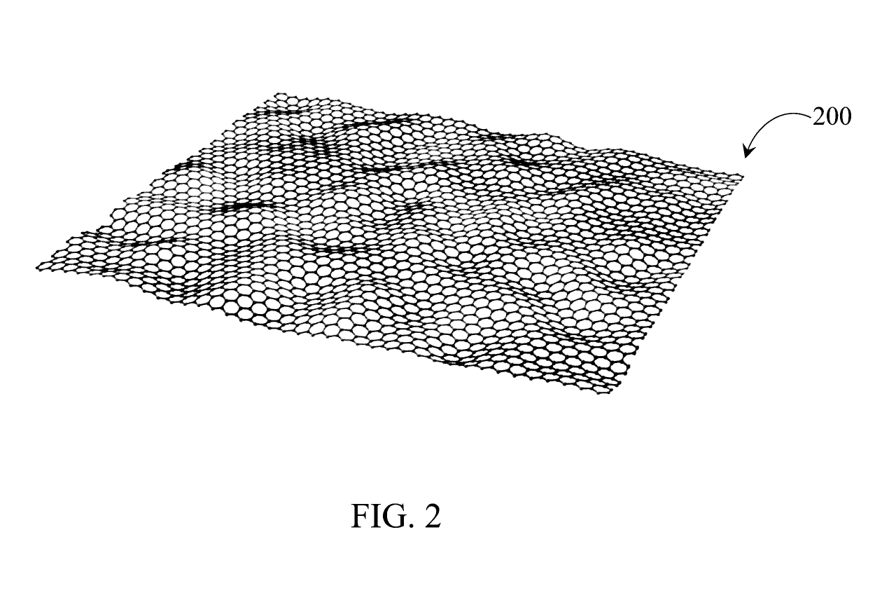

It was found that the growth process of graphene films resulted from the competition of a number of different mechanisms, including CH₄ decomposition, adsorption of carbon species, diffusion of carbon species, and reaction/integration into the crystal lattice. The process was dominated by one mechanism or another, depending on a set of parameters in a multivariable domain, resulting in different qualities of graphene. Instead of low pressure chemical vapor deposition (LPCVD), a higher pressure process with the introduction of Argon was implemented. Thus, the concentration of graphene growth species was diluted, and the amount of oxygen in the system was minimized, both resulting in a controlled growth of monolayer graphene with superior quality. In this manner, a graphene film, as illustrated schematically in FIG. 2, was formed on the copper substrates.

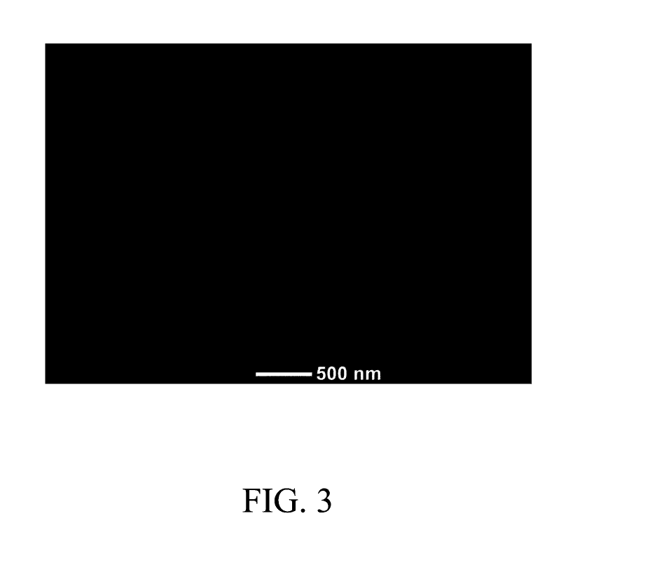

The quality of the CVD graphene films was then examined using scanning electron microscopy (SEM) and Raman spectroscopy. FIG. 3 is a SEM image of a graphene film grown on a copper substrate by CVD. The SEM image showed a uniform and full coverage of the graphene film on the copper substrate.

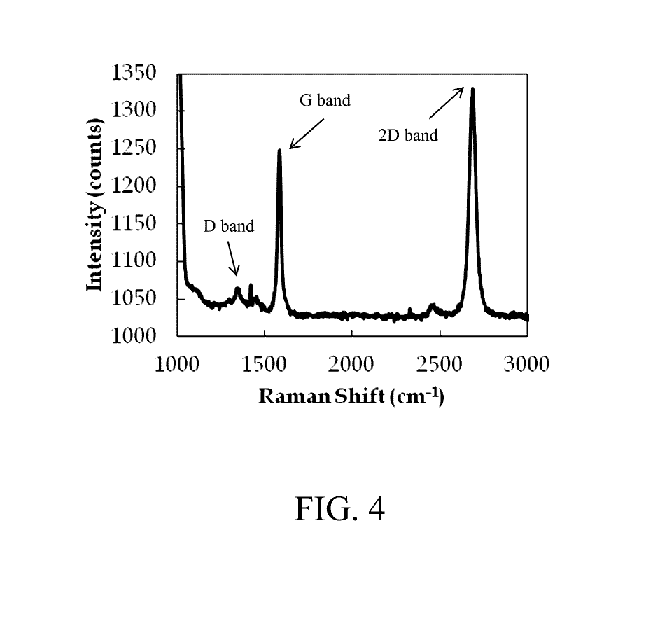

FIG. 4 depicts a Raman spectrum of the graphene film. Raman spectroscopy has been used to determine the defect density and the number of layers in a graphene film. In a Raman spectrum of graphene, there are several significant peaks: D band peak, G band peak, and 2D band peak, located at 1350 cm⁻¹, 1580 cm⁻¹, and 2680 cm⁻¹, respectively. The ratio of the D band peak to the G band peak is an indicator of defects and disorder in the graphene lattice. The higher the D band peak to the G band peak ratio, the more defects and lattice disorder in a graphene film. The ratio of the G band peak to the 2D band peak and the splits of the 2D band peak indicate the number of layers of a graphene film. The higher the G band peak to the 2D band peak ratio, the fewer layers of graphene. The Raman spectrum of FIG. 4 showed a negligible D band peak and a significant ratio of the G band peak to the 2D band peak, which suggested a monolayer of graphene with low defect and lattice disorder was formed.

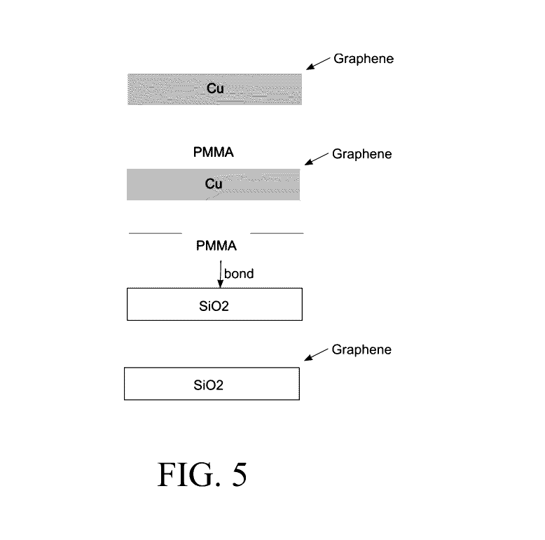

Now refer back to FIG. 1. In an operation 104, the graphene film grown on the copper substrate was transferred to a device substrate. To use the CVD graphene films as transparent conductive electrode for device applications, the films were transferred to a device substrate. FIG. 5 depicts a schematic view of a process of transferring a graphene film from a copper substrate to a device substrate in accordance with an illustrative embodiment. A polymer support was first attached to the graphene film grown on the copper substrate. In some embodiments, the polymer support was poly(methyl methacrylate) (i.e., PMMA) spin-cast onto the graphene film. In other embodiments, the polymer support may be made of other polymer materials, such as, polyethylene terephthalate (PET), polyimide, rubber, etc. It shall be appreciated that the polymer materials given here are for illustrative only, not for limiting. The polymer support may be made of any suitable materials. The stack was then placed PMMA-side-up in a copper etchant to remove the copper substrate. In some embodiments, the copper etchant was iron(III) chloride (FeCl₃) solution. In some embodiments, other copper etchants may be used. The stack was then bonded to the device substrate. In some embodiments, the device substrate was a silicon dioxide substrate, which is a commonly used insulator in fabricating optoelectronic device architectures. In some embodiments, other device substrates may be used. The PMMA residues were then removed from the stack. In some embodiment, the PMMA residues were dissolved in acetone. In some embodiments, the PMMA residues were removed using a thermal annealing. In some embodiments, the PMMA residues were removed using a combination of the two methods. It shall be appreciated, any suitable method may be used to remove the PMMA residues. In this manner, the graphene film may be transferred onto arbitrary substrates.

Now refer back to FIG. 1. In an operation 106, the graphene film was doped with gold(III) chloride (AuCl₃). Chemical doping is a feasible method to reduce the resistance of graphene. It was found that AuCl₃ dopants did not destroy electronic structure of graphene by disrupting the graphene lattice. Instead, AuCl₃ adsorbed onto the graphene lattice. In some embodiments, AuCl₃ in nitromethane (CH₃NO₂) solution having a concentration of 0.001 mole per liter to 0.05 mole per liter was spun on the graphene film at room temperature and atmospheric pressure. The spinning was carried out at 2000 revolutions per minute for about 60 seconds. The solvent nitromethane was then dried in the air. In some embodiments, other organic solvents or water was used as the solvent of the AuCl₃ solution. In this manner, the graphene film was doped with AuCl₃ dopants.

In some embodiments, the doping process was mingled with the transferring process. A polymer support was first attached to the graphene film grown on the copper substrate. The stack was then placed copper-side-down in a copper etchant to remove the copper substrate. The graphene-polymer assembly was then placed graphene-side-down in deionized water to clean the graphene film. After being rinsed in the deionized water, the assembly was placed graphene-side-down in a AuCl₃ solution to be doped with AuCl₃. The assembly was then bonded to a device substrate and the polymer support was removed by thermal or chemical processes.

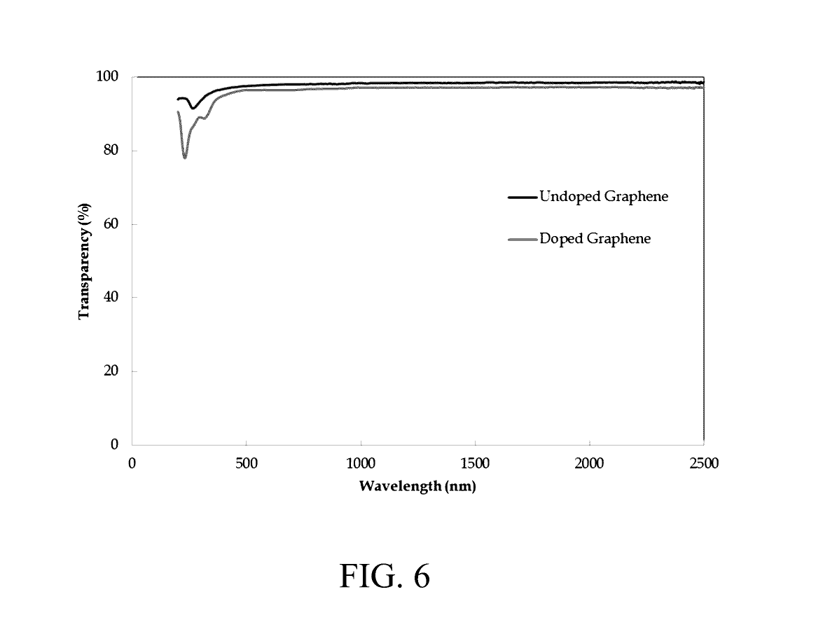

The transmittance and resistance of the doped graphene films were then examined and compared to that of the undoped graphene films. The optical transmittance was measured by a spectrometer from a wavelength of 200 nanometers (nm) to 2000 nm. FIG. 6 is a graph illustrating transmittances of a graphene film doped with AuCl₃ and an undoped graphene film. In the ultraviolet range, the doped graphene film showed lower transmittance than the undoped graphene film, with a dip of about 80% transmittance at a wavelength of about 250 nm. In the visible to infrared range, the dopants had little impact in the transmittance. The doped graphene film showed a homogeneous transmittance of 97% and the undoped graphene film showed a 98% transmittance.

The resistance of the doped and undoped graphene films was measured by a probe station using four-wire resistance measurement. The resistance of three samples was measured before and after doping. For the first sample, the sheet resistance of the graphene film before doping was 2031 Ohms per square, while the sheet resistance after doping was 179 Ohms per square. For the second sample, the sheet resistance of the graphene film before doping was 1120 Ohms per square, while the sheet resistance after doping was 116.5 Ohms per square. For the third sample, the sheet resistance of the graphene film before doping was 2630 Ohms per square, while the sheet resistance after doping was 58 Ohms per square. These measurements showed that both high optical transmittance and low electrical resistance were achieved on the doped graphene films, which were ready for using as transparent conductive electrodes in device applications.

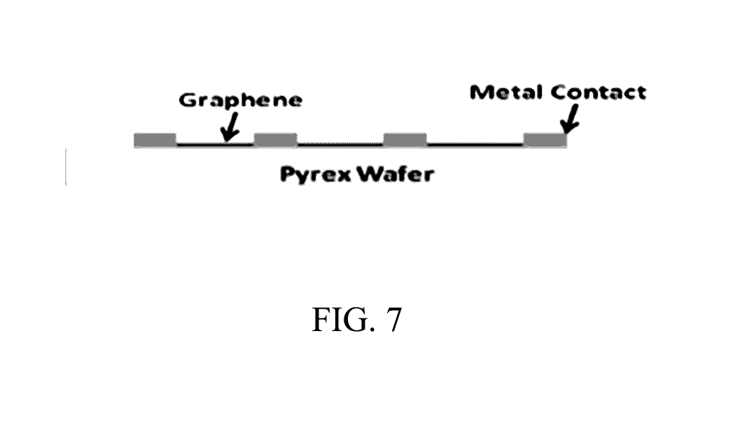

Now refer back again to FIG. 1. In an operation 108, the doped graphene film was patterned for device applications. Since the graphene film was already on the device substrate, photolithography and reactive ion etching (RIE) with oxygen (O₂) plasma were employed to pattern the graphene film. In various embodiments, the graphene film may be patterned differently according to the functions of different devices. FIG. 7 depicts a schematic cross-sectional view of a device with graphene transparent conductive electrodes. In some embodiments, the device is a transparent substrate in microshutter arrays used on the Near Infrared Spectrograph (NIRSpec) instrument on the James Webb Space Telescope (JWST), the Next Generation Space Telescope (NGST).

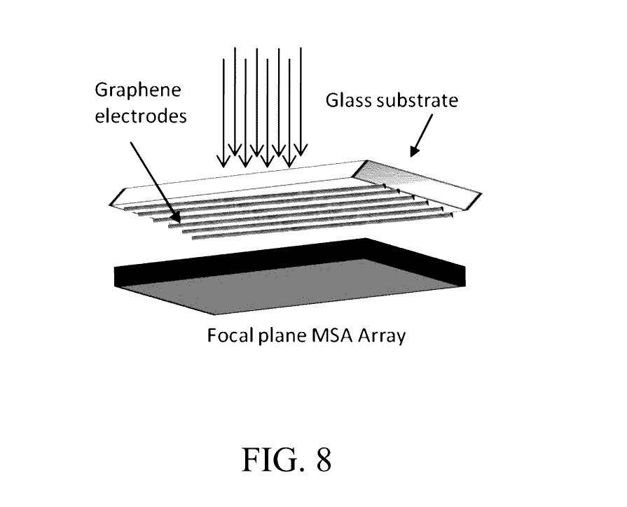

FIG. 8 depicts a schematic perspective view of a microshutter array with graphene transparent conductive electrodes. Microshutter arrays are placed in the telescope optical path at the focal plane of NIRSpec detectors for selective transmission of light. NIRSpec is an instrument that allows simultaneous observation of a large number of objects in space. A microshutter array comprises a plurality of individually controllable microshutter cells. Each microshutter cell can be placed in either an open state or a closed state. An open microshutter cell lets light in from desired objects, while a closed cell blocks light from objects not desired. Given an image of an area on the sky, the microshutter array can be programmed to admit light from an ensemble of selected objects, providing a capability of simultaneous observation of a large number of objects. Graphene electrodes on the glass substrate are used in, for example, actuation mechanism of the microshutter array cells with high transmittance and low resistance.

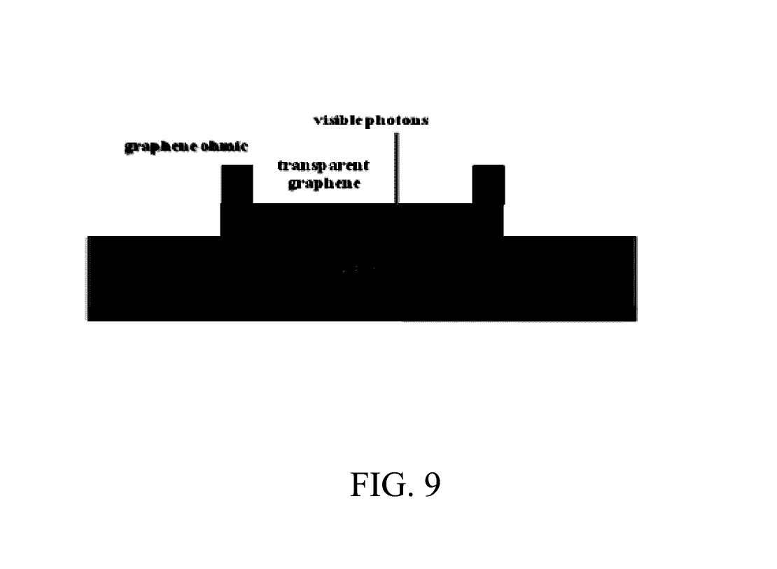

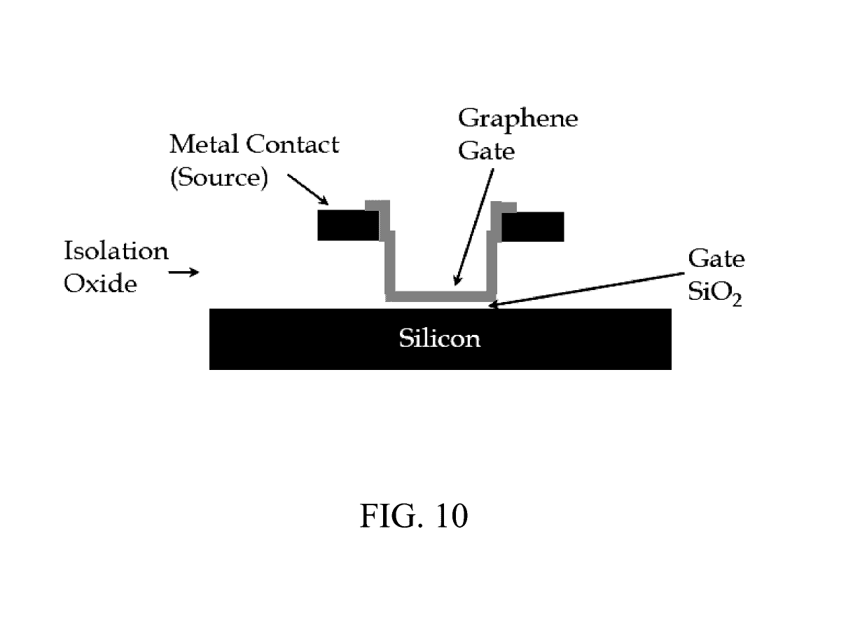

In some embodiments, the doped graphene film is used as transparent conductive electrode in a photovoltaic device. FIG. 9 depicts a schematic cross-sectional view of a photovoltaic device with graphene transparent conductive electrode. In some embodiments, the doped graphene film is used as transparent conductive electrode in a field effect transistor (FET). FIG. 10 depicts a schematic cross-sectional view of a field effect transistor (FET) device with graphene transparent conductive electrode. It shall be appreciated that the examples given here are for illustration only, not for limiting. The high transmittance and low resistance graphene films may be used as transparent conductive electrodes in any suitable device applications.

As utilized herein, the terms “approximately,” “about,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

References herein to the positions of elements (e.g., “on,” “under,” “above,” “below,” “horizontal,” “vertical,” etc.) are merely used to describe the orientation of various elements in the FIGURES. It should be noted that the orientation of various elements may differ according to other exemplary embodiments, and that such variations are intended to be encompassed by the present disclosure.

While various embodiments of the methods and systems have been described, these embodiments are exemplary and in no way limit the scope of the described methods or systems. Those having skill in the relevant art can effect changes to form and details of the described methods and systems without departing from the broadest scope of the described methods and systems. Thus, the scope of the methods and systems described herein should not be limited by any of the exemplary embodiments and should be defined in accordance with the accompanying claims and their equivalents.

What is claimed is:

1. A method of fabricating graphene for device application, the method comprising:
growing a graphene film on a copper substrate using chemical vapor deposition (CVD);
transferring the graphene film from the copper substrate to a device substrate;
doping the graphene film with gold(III) chloride (AuCl₃); and
patterning the graphene film.

2. The method of claim 1, wherein the growing the graphene film on the copper substrate further comprises:
heating the copper substrate in a CVD reactor to a temperature of about 850° C. to about 1000° C. under an ambient pressure of hydrogen (H₂), or argon (Ar), or a mixture thereof; and
introducing reactions gas mixtures to the cooper substrate in the CVD reactor, wherein the reaction gas mixtures include flowing methane (CH₄) of about 1 to about 20 standard cubic centimeters per minute (sccm), flowing H₂ of about 5 to about 50 sccm, and flowing Ar of about 20 to about 1000 sccm, and wherein said introducing reaction gas mixture is carried out for 30 minutes to 60 minutes.

3. The method of claim 1, further comprising:
cooling down the copper substrate at a rate of 25° C. per minute to 35° C. per minute to about 300° C.; and
cooling down the copper substrate naturally from about 300° C. to a room temperature.

4. The method of claim 1, where the transferring the graphene film from the copper substrate to the device substrate further comprises:
attaching a polymer support to the graphene film on the copper substrate to form a stack;
removing the copper substrate from the stack in a copper etchant;
attaching a device substrate to the graphene film; and
removing the polymer support.

5. The method of claim 4, wherein the attaching the polymer support to the graphene film comprises spin-casting a polymer material onto the graphene film.

6. The method of claim 4, wherein the device substrate comprises a silicon dioxide substrate.

7. The method of claim 1, wherein the doping the graphene film with AuCl₃ comprises:
spinning a AuCl₃ solution onto the graphene film, wherein the AuCl₃ solution has a concentration of 0.001 mole per liter to 0.05 mole per liter of AuCl₃ in a nitromethane (CH₃NO₂) solvent, and wherein said spinning is carried out at 2000 revolutions per minute for about 60 seconds; and
drying the nitromethane solvent.

8. The method of claim 1, wherein the transferring the graphene film and the doping the graphene film comprise:
attaching a polymer support to the graphene film grown on the copper substrate to form a stack;
removing the copper substrate from the stack in a copper etchant;
cleaning the graphene film in deionized water;
doping the graphene film with AuCl₃ in a AuCl₃ solution;
attaching a device substrate to the graphene film; and
removing the polymer support.

9. The method of claim 1, wherein the patterning the graphene film comprises etching the graphene film with oxygen plasma.

10. The method of claim 9, wherein the patterning the graphene film comprises using a photolithography mask when etching the graphene film.

11. A graphene film doped with AuCl₃ that has a transmittance of at least 97% in visible to infrared range and a sheet resistance of less than 200 Ohms per square.

12. The graphene film of claim 11, wherein the graphene film is a monolayer graphene.

13. The graphene film of claim 11, wherein the sheet resistance is less than 100 Ohms per square.

14. The graphene film of claim 11, wherein the sheet resistance is less than 60 Ohms per square.

15. A device comprising a graphene transparent conductive electrode, wherein the graphene transparent conductive electrode comprises a graphene film doped with AuCl₃, and wherein the graphene film has a transmittance of at least 97% in visible to infrared range and a sheet resistance of less than 200 Ohms per square.

16. The device of claim 15, wherein the sheet resistance is less than 60 Ohms per square.

17. The device of claim 15, wherein the device comprises a transparent substrate in a microshutter array.

18. The device of claim 16, wherein the microshutter array is on a space telescope.

19. The device of claim 15, wherein the device comprises a photovoltaic device.

20. The device of claim 15, wherein the device comprises a field effect transistor (FET).
